(19) United States
(12) Patent Application Publication
(10) Pub. No.: US 2005/0255668 A1
(43) Pub. Date: Nov. 17, 2005

(54) METHOD OF FABRICATING SHALLOW TRENCH ISOLATION STRUCTURE

(76) Inventors: Shyang-Ming Tseng, Yilan County (TW); Chia-Ping Lai, Hsinchu County (TW); Chih-Ming Chen, Taichung County (TW); Saysamone Pittikoun, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/907,281

(22) Filed: Mar. 28, 2005

(30) Foreign Application Priority Data
May 12, 2004 (TW) 93113275

(51) Int. Cl. H01L 21/76

(52) U.S. Cl. 438/424

(57) ABSTRACT

A method of fabricating a shallow trench isolation (STI) structure is provided. A pad oxide layer, a pad silicon layer and a mask layer are sequentially formed over a substrate. Thereafter, the mask layer and the pad silicon layer are patterned to form an opening that exposes a portion of the pad silicon layer. A spacer is formed on the sidewall of the opening and then a portion of the pad oxide layer is removed to expose a portion of the substrate. A portion of the substrate is removed to form a trench. The spacer is removed and the pad oxide layer is etched back to form an undercut. Next, insulating material is deposited over the substrate to fill the trench. The patterned mask layer, the pad silicon layer, the pad oxide layer and a portion of the insulating material are removed to form the STI structure.

### CROSS-REFERENCE TO RELATED APPLICATION

This application claims the priority benefit of Taiwan application serial no. 93113275, filed on May 12, 2004.

### BACKGROUND OF THE INVENTION

1. Field of the Invention

The present invention relates to a method of fabricating a semiconductor device. More particularly, the present invention relates to a method of fabricating a shallow trench isolation (STI) structure.

2. Description of Related Art

With the rapid progress in integrated circuit technologies, device miniaturization and integration is an important subject. As the size of integrated circuit devices continues to shrink, the level of integration increases but the structures for isolating devices also reduces correspondingly. In other words, increasingly difficult techniques have to be deployed to isolate devices. The conventional isolation structure such as the field oxide layer formed by the local oxidation of silicon (LOCOS) method is no longer suitable when the device is increasingly miniaturized. The so-called bird's beak encroachment often leads to the production of leakage current and results in the appearance of white spots on an image screen.

Because of the difficulties in fabricating miniaturized isolating devices, other methods of isolating devices have been developed. One of the most widely adopted isolation methods is to form a shallow trench isolation (STI) structure. In particular, the STI structure is suitable for fabricating sub-half micron integrated circuits.

To form a conventional STI structure, an oxide pad layer and a silicon nitride mask are sequentially formed over a substrate. An anisotropic dry etching operation is carried out to produce a trench with abrupt sidewalls in the substrate. Thereafter, a liner layer is formed on the surface of the trench by performing a thermal oxidation. Insulating material is deposited over the substrate to fill the trench. Any excess insulating material above the silicon nitride mask is removed. Finally, the silicon nitride mask and the oxide pad layer are removed.

In the aforementioned STI structure, abrupt corners are formed near the top section of the trench. Thus, the gate oxide layer close to the top corners of the STI structure has a thickness smaller than the gate oxide layer in the active region (as shown in FIG. 1). In other words, the capacity of the gate oxide layer for isolation in these corner regions is weakened so that a leakage current easily occurs. On the other hand, if the gate oxide layer is used as a tunneling oxide layer in a memory device, reliability of the memory device will be compromised.

Furthermore, because the liner layer on the surface of the trench is formed by performing a thermal oxidation process to convert a portion of the silicon into silicon oxide, a layer of silicon on next to the surface of the trench is consumed. Hence, the thermal oxidation process expands the profile of the STI structure so that the actual usable active region is reduced. In other words, the process contributes some additional variables to the design and layout of devices that may adversely affect the miniaturization of semiconductor devices.

To resolve the aforementioned problems, some prior arts proposed a method of fabricating a shallow trench isolation (STI) structure. FIGS. 2A through 2C are schematic cross-sectional views showing the steps of fabricating a conventional STI structure. First, as shown in FIG. 2A, a substrate 200 is provided. An oxide pad layer 202 and a silicon nitride layer 204 are sequentially formed over the substrate 200. The silicon nitride layer 204 and the oxide pad layer 202 are patterned to form an opening 206. Thereafter, a spacer 208 is formed on the sidewall of the opening 206.

As shown in FIG. 2B, using the patterned silicon nitride layer 204 and the spacer 208 as an etching mask, a portion of the substrate 200 is removed to form a trench 210. After removing the spacer 208, a pull back etching operation is carried out to undercut the sidewall of the patterned oxide pad layer 202. Thereafter, a liner layer 212 is formed on the sidewall of the trench 210.

As shown in FIG. 2C, silicon oxide is deposited to fill the trench 210. Thereafter, the silicon nitride layer 204 and the oxide pad layer 202 are sequentially removed to form a STI structure 216.

In the process of forming the opening 206, over-etching may occur in an attempt to remove the oxide pad layer 202 completely leading to the formation of a recess in the substrate 200. After etching back the oxide pad layer 202, two separate corners 214 and 214′ are formed at the top section of the trench 210 (as shown in FIG. 2D). This leads to the formation of a highly non-uniform liner layer 212 on the sidewall near a top of the trench 210 (as shown in FIG. 2E). When a high-density plasma chemical vapor deposition (HDPCVD) process is carried out to form a silicon oxide layer, the thin liner layer 212 at the corner region 214 is easily damaged by the bombarding ions. With a damaged liner layer, the capacity of the STI structure to isolate neighboring devices will be compromised and hence leakage current will be a significant problem.

### SUMMARY OF THE INVENTION

Accordingly, the present invention is directed to a method of fabricating a shallow trench isolation (STI) structure that utilizes a spacer and a mask layer as an etching mask to form a narrower trench in a substrate. Hence, the subsequent formation of a liner layer on the surface of trench will not expand the sectional profile of the STI structure too much. Ultimately, a larger active region for forming semiconductor devices is provided.

The prevent invention is also directed to a method of fabricating a shallow trench isolation (STI) structure that produces a trench with round top corners. Hence, the subsequently formed gate oxide layer will have a more uniform thickness and thereby reduce any leakage current at the top section of the STI structure or the upper region adjacent to the active devices.

According to an embodiment of the present invention, first, a substrate is provided. An oxide pad layer, a silicon pad layer and a mask layer are sequentially formed over the substrate. Thereafter, the mask layer and the silicon pad layer are patterned to form an opening that exposes a portion of the silicon pad layer. A spacer is formed on the sidewall of the opening and then a portion of the oxide pad layer is removed to expose a portion of the substrate. Using the mask layer with the spacer as an etching mask, a portion of the substrate is removed to form a trench. The spacer is removed and the oxide pad layer is etched back to form an undercut. Next, insulating material is deposited over the substrate to fill the trench. The patterned mask layer, the silicon pad layer, the oxide pad layer and a portion of the insulating material are removed to form the STI structure.

The present invention is also directed to an alternative method of fabricating a shallow trench isolation (STI) structure. First, a substrate having an pad layer and a mask layer already formed thereon is provided. The mask layer is patterned to form an opening that exposes a portion of the pad layer. Thereafter, a pair of spacers is formed on the sidewall of the opening. Using the mask layer with the spacers as an etching mask, a portion of the pad layer and the substrate is removed to form a trench in the substrate. The spacer is removed and the pad layer is etched back to form an undercut under the pad layer. Next, insulating material is deposited over the substrate to fill the trench. The patterned mask layer and the pad layer are removed. Finally, a portion of the insulating material is removed to form the STI structure.

In the present invention, the spacer and the mask layer is used as an etching mask to form a narrower trench in the substrate. Therefore, the process of forming the liner layer on the sidewall of the trench will not expand the profile of the STI structure too much. In other words, the process is able to provide a larger active region for forming semiconductor devices. Furthermore, the present invention provides a method of forming a trench with round upper corners so that a subsequently formed gate oxide layer can have a more uniform thickness. Hence, the chance of developing a leakage current at the top section of the STI structure or the upper region adjacent to the active devices is minimized.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a picture taken by a electron microscope showing a gate oxide layer formed near a top corner region of a STI structure fabricated using a method according to an embodiment of the present invention and taken by a transmission electron microscope.

FIGS. 2A through 2C are schematic cross-sectional views showing the steps of fabricating a conventional STI structure.

FIG. 2D is a magnified view showing two corners at the top section of a trench formed by the conventional process.

FIG. 2E is a magnified view showing a liner layer on the sidewall of the trench formed by the conventional process.

FIGS. 3A through 3G are schematic cross-sectional views showing the steps of forming a shallow trench isolation structure according to an embodiment of the present invention.

FIG. 4 is a picture taken by an electron microscope showing a STI structure fabricated using a method according to an embodiment of the present invention.

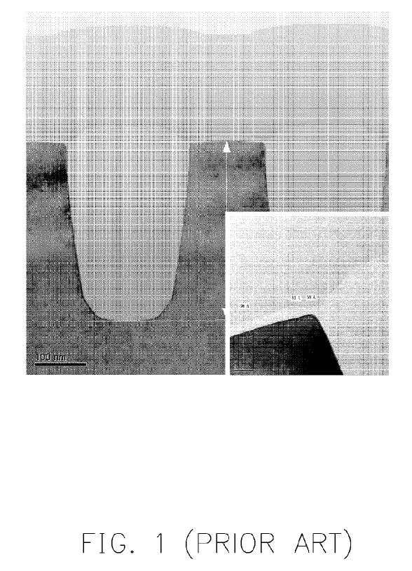

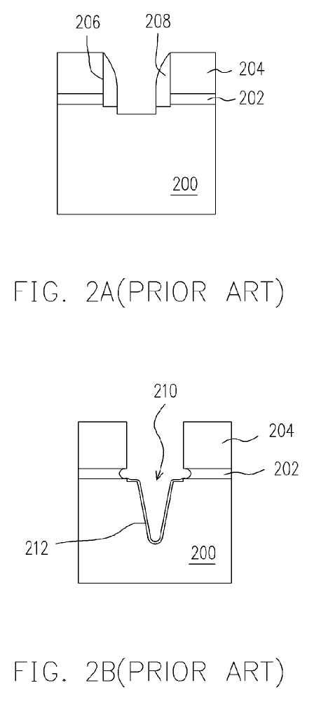

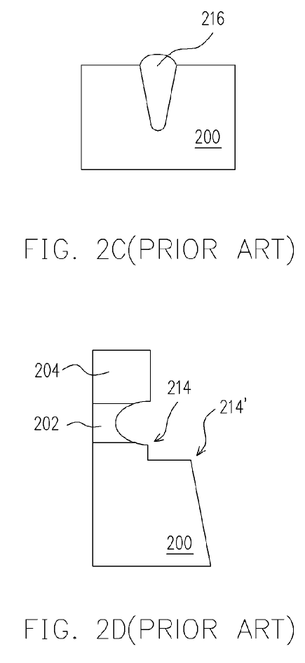

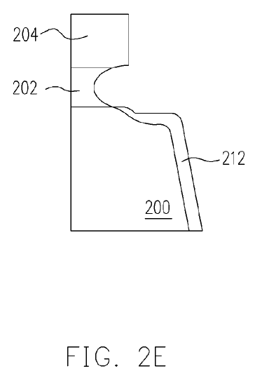

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

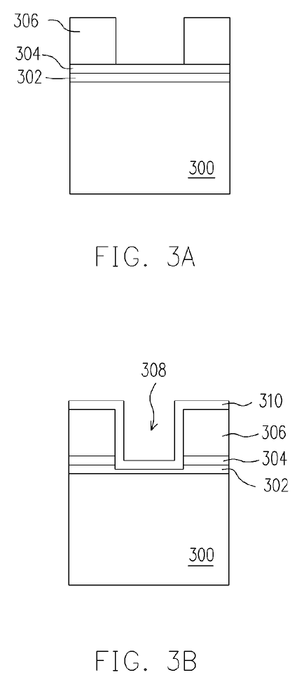

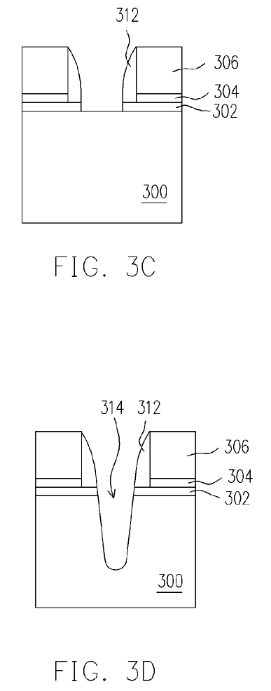

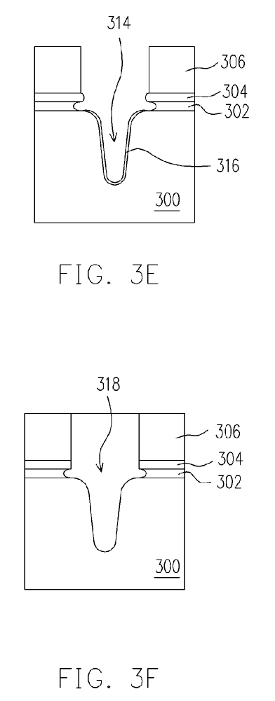

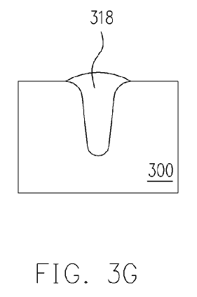

FIGS. 3A through 3G are schematic cross-sectional views showing the steps of forming a shallow trench isolation structure according to an embodiment of the present invention. As shown in FIG. 3A, a substrate 300 is provided. Thereafter, a pad oxide layer 302 is formed over the substrate 300. The pad oxide layer 302 is, for example, a silicon dioxide layer formed by, for example, a thermal oxidation process. Obviously, the pad oxide layer 302 can be fabricated using other suitable materials. Next, a pad silicon layer 304 is formed over the pad oxide layer 302. The pad silicon layer 304 can be a polysilicon layer, an amorphous silicon layer or a mono-crystalline layer formed in a chemical vapor deposition process, for example. A patterned mask layer 306 is formed over the pad silicon layer 304. The mask layer 306 can be a silicon nitride layer formed in a chemical vapor deposition process, for example. Obviously, the mask layer 306 can be fabricated using other suitable materials. Moreover, the pad silicon layer 304 is optional. In other words, the step of forming the silicon pad layer 304 can be skipped.

As shown in FIG. 3B, using the patterned mask layer 306 as an etching mask, a portion of the silicon pad layer 304 is removed to form an opening 308 that exposes a portion of the oxide pad layer 302. Thereafter, a conformal dielectric layer 310 is formed over the substrate 300. The dielectric layer 310 can be a silicon dioxide layer formed in a chemical vapor deposition process, for example.

As shown in FIG. 3C, an anisotropic etching process is carried out to remove a portion of the dielectric layer 310 so that a spacer 312 is formed on the sidewall of the opening 308. Thereafter, the exposed pad oxide layer 302 within the opening 308 is removed. If the pad oxide layer 302 and the dielectric layer 310 are fabricated using an identical material, the pad oxide layer 302 within the opening 308 can be removed in the same etching process for forming the spacer 312.

As shown in FIG. 3D, using mask layer 306 with the spacer 312 as an etching mask, a portion of the substrate 300 exposed by the opening 308 is removed to form a trench 314.

As shown in FIG. 3E, the spacer 312 is removed, for example, by performing a wet etching operation using hot hydrofluoric acid (for example, hydrofluoric acid heated to 110° C.) as an etchant. Thereafter, a back etching operation is carried out to undercut the pad oxide layer 302. The pad oxide layer 302 is etched back by performing a wet etching operation using hydrofluoric acid as the etchant, for example. The surrounding top section of the trench 314 is exposed after the oxide pad layer 302 retracts inward. A liner oxide layer 316 is formed over the surface of the trench 314. The liner oxide layer 316 is formed, for example, by performing a thermal oxidation. Because oxygen reacts with the exposed silicon on the surface of the trench 314 to form the silicon oxide liner layer 316, the top corners of the trench 314 are rounded after lattice re-crystallization. Thus, the process improves the uniformity and thickness of a subsequently formed gate oxide layer.

As shown in FIG. 3F, insulating material 318 is deposited over the substrate 300 to fill the trench 314. The insulating material layer 318 is a silicon dioxide layer formed in a high-density plasma chemical vapor deposition (HDP-CVD) process, for example. Thereafter, the insulating material layer 318 is planarized to expose the mask layer 306. The insulating material 318 is planarized, for example, by performing a chemical-mechanical polishing (CMP) operation.

As shown in FIG. 3G, the patterned mask layer 306, the pad silicon layer 304, the pad oxide layer 302 and a portion of the insulating material layer 318 is removed to form a shallow trench isolation (STI) structure 320. The patterned mask layer 306, the silicon pad layer 304, the oxide pad layer 302 and the insulating material layer 318 are removed, for example, by performing a wet etching operation. For example, if the mask layer 306 is a silicon nitride layer, hot phosphoric acid is used as the etchant for removing the mask layer 306. To remove the pad silicon layer 304, a mixture containing nitrous acid and hydrofluoric acid is used as the etchant. To remove the pad oxide layer 302 and a portion of the insulating layer 318, hydrofluoric acid (HF) is used as the etchant.

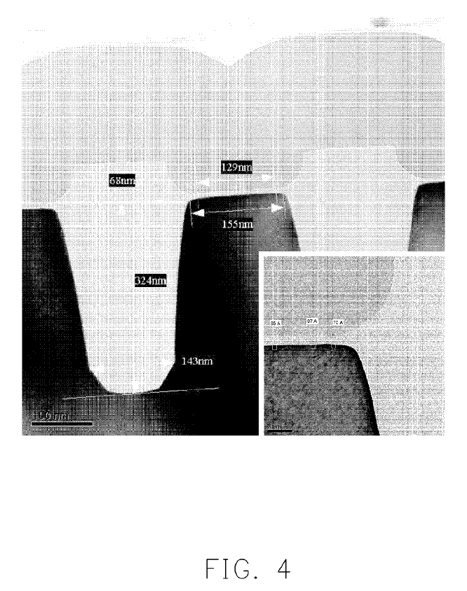

In the aforementioned embodiment, the spacer 312 and the mask layer 306 are used as an etching mask to form a narrower trench in the substrate 300. Hence, the formation of the liner oxide layer 316 on the sidewall of the trench will not expand the profile of the STI structure too much. Furthermore, after removing the spacer 312 and undercutting the pad oxide layer 302, the surrounding area at the top section of the trench 314 is exposed. Later on, the silicon on the trench surface is permitted to react with oxygen to form a silicon oxide layer. After lattice reorganization, the top corners of the trench 314 are rounded. Therefore, thickness and uniformity of a subsequently formed gate oxide layer will be improved. FIG. 4 is a picture taken by an electron microscope showing the STI structure fabricated using the method according to an embodiment of the present invention. As shown in FIG. 4, the top corners of the trench 314 in the STI structure 320 has a smooth profile so that the subsequently formed gate oxide layer has a uniform thickness.

In summary, the advantages of the present invention at least includes as follows.

1. A spacer and a mask layer are used as an etching mask to form a narrower trench in the substrate. Through the formation of a liner oxide layer, the top corners of the trench are rounded. Since the formation of a narrower trench and the liner oxide layer tends to complement each other, the method will neither affect the profile of the STI structure nor reduce the active region.

2. The rounding of the upper corners of a trench facilitates the subsequent fabrication of a gate oxide layer with substantially uniform thickness and reduce current leakage from the top section of the STI structure or the top area adjacent to the active devices.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A method of fabricating a shallow trench isolation (STI) structure, comprising the steps of:
providing a substrate having a pad oxide layer, a pad silicon layer and a mask layer sequentially formed thereon;
patterning the mask layer and the pad silicon layer to form an opening that exposes a portion of the oxide pad layer;
forming a spacer on the sidewall of the opening and removing a portion of the pad oxide layer to expose a portion of the substrate;
removing a portion of the substrate to form a trench using the mask layer and the spacer as an etching mask;
removing the spacer;
etching back the oxide pad layer to form an undercut;
depositing an insulating material to fill the trench;
removing the patterned mask layer, the silicon pad layer and the oxide pad layer; and
removing a portion of the insulating material to form the STI structure.

2. The method of claim 1, wherein the step forming a spacer on the sidewall of the opening comprises:
forming a silicon oxide layer over the substrate; and
performing an anisotropic etching process to remove a portion of the silicon oxide layer.

3. The method of claim 2, wherein the step of forming the silicon oxide layer comprises performing a chemical vapor deposition process.

4. The method of claim 1, wherein the material constituting the pad oxide layer comprises silicon oxide.

5. The method of claim 1, wherein a material constituting the pad silicon layer comprises polysilicon.

6. The method of claim 1, wherein a material constituting the mask layer comprises silicon nitride.

7. The method of claim 1, further comprising a step of forming a liner oxide layer over the sidewall of the trench and the pad silicon layer before the step of depositing insulating material into the trench.

8. The method of claim 6, wherein the step of forming the liner oxide layer comprises performing a thermal oxidation process.

9. The method of claim 1, wherein a material constituting the insulating material layer comprises silicon dioxide.

10. The method of claim 1, wherein the step of depositing insulating material comprises performing a high-density plasma chemical vapor deposition (HDP-CVD) process.

11. The method of claim 1, wherein the step of depositing insulating material into the trench further comprises:
depositing insulating material over the substrate; and
removing a portion of the insulating material to expose the mask layer.

12. The method of claim 11, wherein the step of removing a portion of the insulating material layer to expose the mask layer comprises performing a chemical-mechanical polishing operation.

13. A method of fabricating a shallow trench isolation (STI) structure, comprising the steps of:
providing a substrate having an pad layer and a mask layer formed thereon;
patterning the mask layer to form an opening that exposes a portion of the pad layer;
forming a pair of spacers on the sidewall of the opening;
removing a portion of the pad layer and the substrate to form a trench in the substrate using the spacers and the mask layer as an etching mask;
removing the spacers;
etching part of the pad layer to form an undercut under the -mask layer;
depositing insulating material to fill the trench;
removing the patterned mask layer and the pad layer; and
removing a portion of the insulating material to form the STI structure.

14. The method of claim 13, wherein a material constituting the pad layer comprises silicon oxide.

15. The method of claim 14, wherein the step of forming the silicon oxide layer comprises performing a chemical vapor deposition process.

16. The method of claim 13, wherein a material constituting the mask layer comprises silicon nitride.

17. The method of claim 13, further comprising a step of forming a liner oxide layer on the sidewall of the trench before the step of depositing insulating material into the trench.

18. The method of claim 17, wherein the step of forming the liner oxide layer comprises performing a thermal oxidation process.

19. The method of claim 13, wherein a material constituting the insulating layer comprises silicon dioxide.

20. The method of claim 13, wherein the step of forming a spacer on the sidewall of the opening comprises:
forming a silicon oxide layer over the substrate; and
performing an anisotropic etching operation to remove a portion of the silicon oxide layer.
